(19) United States
(12) Patent Application Publication
(10) Pub. No.: US 2014/0262469 A1
(43) Pub. Date: Sep. 18, 2014

(54) RADIO FREQUENCY FEEDTHROUGH

(71) Applicant: Schott AG, Mainz (DE)

(72) Inventors: Robert Hettler, Kumhausen (DE); Thomas Zetterer, Landshut (DE); Kenneth Tan, Singapore (SG); Karsten Droegemueller, Eichenau (DE)

(73) Assignee: Schott AG, Mainz (DE)

(21) Appl. No.: 14/210,159

(22) Filed: Mar. 13, 2014

(30) Foreign Application Priority Data
Mar. 18, 2013 (DE) 10 2013 102 714.8

(51) Int. Cl. H05K 1/11

(52) U.S. Cl. CPC H05K 1/115
USPC 174/262

(57) ABSTRACT

A radio frequency feedthrough for optoelectronic housings is provided that includes a multilayer ceramic body and a signal conductor that extends through the ceramic layers in an S-shape. In an upper region of the multilayer ceramic body, a ground layer is recessed in a V-shape, and in a central region of the multilayer ceramic body the signal conductor extends coaxially.

### CROSS REFERENCE TO RELATED APPLICATIONS

This application claims benefit under 35 U.S.C. §119(a) of German Patent Application No. 10 2013 102 714.8, filed Mar. 18, 2013, the entire contents of which are incorporated herein by reference.

### BACKGROUND OF THE INVENTION

1. Field of the Invention

The invention relates to a feedthrough for radio frequency signals. More particularly, the invention relates to a Surface Mounted Device (SMD) compatible feedthrough for integrated coherent receiver and integrated coherent transmitter modules.

2. Description of Related Art

Integrated Coherent Receiver (ICR) and Integrated Coherent Transmitter (ICT) modules are used especially for data transmission over long-haul links in fiber-optic networks, for amplification of light signals, and for controlling data streams. Such modules convert optical signals into electrical signals, and vice versa.

Currently, transmission is accomplished at data rates of 10 to almost 40 Gbps, requiring hermetically encapsulated housings for the necessary optoelectronics with electrical feedthroughs through the housing wall. In order to achieve transmission rates of 100 Gbps, four radio frequency feedthroughs are operated in parallel, each with 25 Gbps, for example.

The feedthroughs should provide for low attenuation and low reflection. For this purpose, inter alia, the impedance of the signal conductor which may be considered as a waveguide should remain constant along its path through the feedthrough.

From practice, coaxial plug-in connectors are known, which can be soldered into the housing wall. However, these are rather expensive and require additional effort to be compatible with the components in the housing.

Also known from practice are radio frequency feedthroughs that comprise high-temperature multilayer ceramics referred to as High Temperature Cofired Ceramics (HTCC). These have the advantage that indeed a hermetically sealed feedthrough can be achieved. This type of feedthrough moreover allows for a much higher packing density than coaxial connectors.

HTCC ceramics are sintered at 1600 to 1800° C. With this technology, electrical vias can be printed with high precision using a metal paste mostly containing tungsten. The metal pattern accessible at the surface may additionally be electroplated with nickel and/or gold to create solderable and/or bondable surfaces.

For many applications, SMD compatibility of the feedthrough is desired.

The problem is that in an optical receiver or transmitter, the optical plane is not at the surface of the circuit board but offset therefrom.

Currently known feedthroughs of multilayer ceramics are usually not SMD compatible, since the level offset would lead to unacceptable signal loss if it would be realized in the area of the leadframes/outside terminal, for example.

In particular it has not been managed, or only with great complexity, to provide a sufficiently uniform impedance characteristic over the entire area between the optical plane and the level of the circuit board.

### SUMMARY

An object of the invention therefore is to provide a multilayer ceramic SMD compatible feedthrough for radio frequency signals, which is easy to produce.

The invention should in particular allow to provide SMD compatible feedthroughs for housings compliant with the OIF (Optical Internetworking Forum) standard for 100 Gbps transmission links.

The invention relates to an SMD compatible feedthrough for radio frequency signals, i.e. a feedthrough for a module that can directly be soldered onto a circuit board.

The feedthrough comprises a multilayer ceramic body, preferably a sintered multilayer HTCC body.

Further, the feedthrough comprises a first, lower terminal which is spaced apart from a second, upper terminal in a vertical direction.

Lower and upper terminal refers to the typical mounting position. It will be understood that lower and upper as well as vertically upwards and vertically downwards are interchangeable. Also, in particular, it is typically possible to operate the SMT compatible feedthroughs of the invention in both directions.

Because of the vertical offset between the lower terminal and the upper terminal it is possible to arrange the lower terminal substantially at the level of the circuit board, while the upper terminal is preferably arranged approximately at the level of the optical plane of the housing, i.e. at the level at which light signals are introduced into the housing or emitted from the housing.

At least one signal conductor extends through the multilayer ceramic body.

This signal conductor is in particular composed of individual signal conductor sections, which for example were produced by a stamping process to produce small holes in a green sheet, followed by a filling process, e.g. using a printing method. By stacking individual layers and exactly positioning the vias one above the other, electrical feedthroughs are produced in a direction perpendicular to the processing plane of the ceramic layers in this manner. By combination with sections of horizontal printed conductive traces, electrical feedthroughs of virtually any vertical or horizontal course may be realized by having them running through the ceramic layers in stepped manner.

In order to provide the signal conductor with a shield, the layers of the ceramic body have ground layers printed thereon, which are recessed at least around the signal conductor, and the ground layers are interconnected by ground vias that extend through the layers of the ceramic body. In this manner, the signal conductor is shielded similar to a coaxial line.

Therefore, in manufacturing, the ceramic body is provided with holes, layer by layer, for example by punching, the holes are filled with a metal paste and optionally printed, with a dielectric area being provided around the signal conductor due to a recess in the metallization.

Because of the lower terminal and the upper terminal it is necessary that the main extension direction of the signal conductor within the feedthrough changes several times, so that the signal conductor which is formed by individual signal conductor vias extends in an approximately S-shape through the feedthrough.

The associated change in direction of the signal may cause signal loss.

The invention therefore suggests that the recess around the signal conductor widens in the layer of the second, upper terminal behind an end of the terminal.

The inventors have found that by such an enlarged dielectric zone, the change in direction of the signal from a horizontal to a vertical direction can be influenced in a manner so that signal loss is significantly reduced.

In the uppermost layer of the feedthrough, the terminal of the signal conductor preferably forms a coplanar line with the ground conductor, i.e. a planar conductor as a signal conductor adjoined by ground conductors which are also formed as planar conductors.

This coplanar line is interrupted on its way to the vertical portion of the feedthrough thereby creating an imperfection.

The electromagnetic field is widened in a manner so as to be adapted to the geometry of the signal conductor in the vertical portion in which the signal conductor is preferably configured as a coaxial conductor. Preferably, the recess widens in a V-shape as seen from an end of the terminal of the signal conductor in the direction of the interior of the housing when properly installed.

The edges of the V-shaped recess preferably form an angle of between 20° and 90°, more preferably of between 30° and 60°.

Below the first ground layer having a V-shaped recess, the ground layers preferably have a recess of a substantially circular shape around the signal conductor.

The circular recess may even have an approximate polygon shape.

In this manner, preferably, a coaxial line is defined below the upper layer.

In one embodiment of the invention, an extension is provided in the ground layer below the widening recess, which protrudes into the circular recess below the signal conductor.

This extension in a ground layer also serves for signal shaping upon signal entry or exit.

Preferably the extension is formed to be wider than the overlying signal conductor.

In a preferred embodiment of the invention, the ground vias are arranged annularly around the signal conductor, and the individual conductors of the individual ground vias are arranged offset to one another from layer to layer of the ceramic body.

In this manner, manufacturing accuracy upon sintering of the ceramic body can be improved, since the ceramic material and the sintered material from which the electrical vias are printed do not behave the same, and therefore, by arranging the vias to be offset to one another, the risk of deformation due to pressure points is reduced.

The invention further relates to an SMD compatible feedthrough, in particular an SMD compatible feedthrough as described above, which thus comprises a multilayer ceramic body through which a signal conductor extends.

In order to provide a spacing between an upper terminal and a lower terminal, the signal conductor extends through the ceramic body in an S-shape. To this end, the signal conductor comprises, starting from the lower terminal, several, i.e. at least two, offset and interconnected signal conductor vias, whereby the signal conductor is guided from a horizontal direction to a vertical direction.

Connection is made via a conductive layer, i.e. a planar conductor on the upper surface of the respective ceramic layer, which may for example be printed together with the ground layer.

In this manner, the signal conductor is guided to a central region of the feedthrough in which it is defined by superposed signal conductor vias, which are arranged coaxially in recesses of the ground layers.

In an upper region, the signal conductor is re-guided to a horizontal direction, again through a plurality of mutually offset signal conductor vias, which are connected to one another.

A particular advantage of this embodiment is that in a central region the signal conductor is formed like a coaxial conductor, with the signal conductor vias coaxially arranged in the circular recesses of the ground layers of the individual ceramic layers.

Preferably, at least 5 successive layers are formed as a coaxial conductor.

One advantage, among others, of such a coaxial configuration is that it is rather insensitive to manufacturing tolerances.

In particular, a slight offset of the individual signal conductor vias only results in a slight change in the characteristic of the feedthrough as a whole.

In one embodiment of the invention, at least one further ceramic layer is arranged above the layer of the upper terminal, which further layer is intended as a frame for mounting a housing part.

In particular, it is suggested to apply a plurality of ceramic layers on top of the uppermost layer of the signal conductor, which occupy a smaller area than the ceramic layers underneath through which the ground conductor extends. Thus, the terminal region of the signal conductor is exposed.

Further metal layers may then be applied to the ceramic layers, which metal layers are used as a solder pad for a housing part.

Preferably an underneath layer of the ceramic layers that are applied as a frame occupies at least the same area as each of the overlying layers.

That means, the layers preferably are of the same size or stacked in a pyramidal configuration, so that no layer does protrude beyond another. In this manner, stability of the composite is increased.

The ceramic body preferably comprises from 5 to 100 layers, more preferably from 10 to 25 layers.

In order to adapt the height of the feedthrough to the particular application purpose, the number of ceramic layers may be varied, in particular in the central region of the feedthrough.

This possibility is in particular provided in a simple way, if the signal conductor is configured as a coaxial conductor in the central region.

So, the characteristics, in particular the impedance, of the central region does not change by addition or omission of ceramic layers, and at most attenuation increases slightly.

### BRIEF DESCRIPTION OF THE DRAWINGS

FIG. 1 shows a perspective view of a prior art housing;

FIG. 2 shows a schematic sectional view of an SMD compatible feedthrough according to the present disclosure;

FIG. 3 illustrates an exemplary embodiment of feedthrough having a multilayered ceramic body according to the present disclosure;

FIG. 4 illustrates a side view in form of a wireframe view of the feedthrough of FIG. 3;

FIG. 5 is a wireframe view of the uppermost ceramic layers shown in FIG. 3 and of the underlying ceramic layer in a wireframe view;

FIG. 6 shows a configuration of the feedthrough in FIG. 2; and

FIG. 7 shows a wireframe view of the lower region of the feedthrough in FIG. 2.

### DETAILED DESCRIPTION

The subject of the invention will now be explained in more detail with reference to the drawings of FIGS. 1 to 7 by way of schematically illustrated exemplary embodiments.

FIG. 1 shows a perspective view of a housing known from practice, such as it is used for optoelectronic modules.

Housing 1 comprises an optical input 2 which defines the optical plane.

Housing 1 provides space for electronic components for converting a light signal into an electric signal, or vice versa.

The electronic components (not shown) are connected via signal conductors.

For this purpose, housing 1 comprises a ceramic body formed as a feedthrough 5.

Terminals 3a and 3b extend through the feedthrough to terminals 4a and 4b which are arranged inside the housing.

Thus, electronic devices (not shown) may be connected to terminals 4a and 4b inside the housing bonding wires.

In this exemplary embodiment, seven signal conductors are provided on both sides.

The housing is sealed hermetically.

For a hermetically sealed housing, in particular a multilayered ceramic feedthrough 5 is suitable.

The multilayered ceramic in this case comprises a sintered material including printed conductive traces.

A problem, however, is to guide the radio frequency signal within the feedthrough.

In the feedthrough shown herein, the conductive traces extend through the feedthrough 5 in rectilinear manner in one plane.

This permits, for example, to provide a low attenuation and low reflection feedthrough, by using a coplanar conductor.

However, since in this case terminals 4a, 4b inside the housing have to be arranged at the level of the optical plane defined by optical input 2, terminals 3a and 3b outside the housing are also at approximately the same level, whereby the housing 1 illustrated herein is not SMD compatible.

Referring now to FIG. 2, the basic principle of the invention will be explained in more detail.

FIG. 2 shows a schematic sectional view of an SMD compatible feedthrough 5.

Though only one signal conductor is illustrated herein, it will be understood that the feedthrough of the invention may comprise a plurality of signal conductors, similar to the feedthrough shown in FIG. 1.

Feedthrough 5 comprises a ceramic body 8 made of a sintered multilayer high-temperature ceramic.

Feedthrough 5 further comprises a signal conductor 9 which enables to transmit a radio frequency electric signal from inside a housing to the outside of the housing, and vice versa.

Signal conductor 9 has a lower terminal 6 at a lower end of feedthrough 5, and an upper terminal 7 at an upper end of feedthrough 5.

Lower terminal 6 and upper terminal 7 are spaced from one another, so that lower terminal 6 may be located in approximately the plane of the circuit board, so that the housing is SMD compatible.

Upper terminal 7 may be located in the optical plane of the housing.

Further, it can be seen that signal conductor 9 has to change direction several times in stepped manner, so that it extends through the feedthrough in approximately an S-shape.

To this end, starting from lower terminal 6, a lower region 10 is provided, in which the signal conductor changes its direction to run vertically upwards in a central region 11.

In an upper region 12, signal conductor 9 is again stepped so as to extend horizontally from upper terminal 7.

At one side, the feedthrough may additionally comprise a frame 13 which may be formed of one or more ceramic layers.

A metal layer 14 may be arranged on frame 13, which is used for soldering housing components.

Instead of a frame, a metallization 26 may be applied at one side of the ceramic layer of upper terminal 7.

With reference to FIG. 3, it will be explained how the principle illustrated in FIG. 2 is implemented using a multilayered ceramic body.

Feedthrough 5 is formed of multiple layers comprising a plurality of ceramic layers 15a, 15b.

The signal conductor is formed in sections, by signal conductor vias 18b, 18c which are stacked on each other. In the central region (11 in FIG. 2) these conductor sections extend substantially vertical, that is perpendicular to the surface of ceramic layers 15a, 15b.

Ceramic layers 15a, 15b are provided with ground layers 16a, 16b, i.e. they are metalized on their surface.

In the area of conductor vias 18b, 18c, the ground layers 16a, 16b are recessed.

Further, the individual ground layers 16a, 16b are contacted to one another from layer to layer by ground vias 19.

Ground vias 19 are arranged circularly, at least partially, around signal conductor vias 18b, 18c.

The ground vias of each individual layer are offset with respect to those of adjacent layers, so as to reduce deformation or geometrical deviations due to the ground vias 19 during sintering of the body.

Further, upper terminal 7 can be seen, which is configured as a coplanar conductor, and lower terminal 6 which is soldered to a circuit board 20 in this illustration.

Extending adjacent to lower terminal 6 are two ground terminals 17.

The feedthrough preferably has a height from 2 to 10 mm between the upper and lower terminals. The individual ceramic layers preferably have a height from 0.1 to 0.5 mm.

FIG. 4 illustrates a side view in form of a wireframe view of the feedthrough 5 shown in FIG. 3. With reference to FIG. 4, in particular the configuration of the signal conductor will be explained in detail.

Starting from an upper terminal 7 which is configured as a coplanar conductor, a first ceramic layer includes a first signal conductor via 18a to a second ceramic layer. Via 18b of the second ceramic layer is arranged offset from signal conductor via 18a and already defines the beginning of the central vertically extending section of the signal conductor (11 in FIG. 2). Vias 18a and 18b are electrically connected through a conductive trace (not shown) printed on the ceramic layer.

From signal conductor via 18b until a signal conductor via 18c illustrated herein, the signal conductor vias extend vertically through the feedthrough being directly stacked one upon another.

In this central region, the so defined signal conductor is surrounded by an annularly distributed arrangement of ground vias which interconnect the ground layers on the individual ceramic layers.

Signal conductor vias 18a, 18c and ground vias 19 thus form a coaxial conductor.

Though the outer conductor of this coaxial conductor is not closed, the spacing between the individual vias is smaller than a quarter wavelength, so that the signal cannot escape to the outside, or only strongly attenuated.

In the lower region, the signal conductor again changes its direction by having signal conductor vias 18d and 18e arranged offset to signal conductor via 18c.

Signal conductor vias 18c, 18d, and 18e again are electrically connected through a metallization of the respective ceramic layer.

At lower terminal 6, the signal conductor extends horizontally again.

Further, a frame can be seen, which is formed by further ceramic layers 21a and 21b.

With reference to FIG. 5, the configuration of the signal conductor and the ground conductors in the region of the upper terminal will be described in more detail.

FIG. 5 is a wireframe view of the uppermost ceramic layers 15a shown in FIG. 3 and of the underlying ceramic layer in a wireframe view.

Upper terminal 7 can be seen, which forms a horizontally extending section of the signal conductor. It has a typical width of conductive traces in a range from 50 to 300 μm.

As can further be seen, a ground layer 16a is provided on the uppermost ceramic layer, which ground layer is recessed along the lateral edge of terminal 7 which is formed as a coplanar conductor.

Terminal 7 ends at signal conductor via 18a. From this area, the recess of ground layer 16a widens in a rearward direction to form a V-shaped recess 22 which extends to the vicinity of annularly arranged ground vias 19. Below the first ceramic layer, another ceramic layer is arranged in which an offset signal conductor via 18b is provided.

Signal conductor via 18b is already arranged coaxially between annularly arranged ground vias 19.

Uppermost signal conductor via 18a is connected to the signal conductor via 18b below by conductive trace 23 provided on the surface of the ceramic layer.

From the region of signal conductor via 18b, the ground layer arranged below ground layer 16a is recessed around signal conductor via 18b, forming a circular recess 24 in this layer and the subsequent layers below.

An extension 25 protrudes into the first circular recess 24 of the ground layer arranged below ground layer 16a. This extension is wider than terminal 7.

The V-shaped recess 22 of ground layer 16 and the underlying extension 25 will shape the signal so that it can enter the coaxial path below which extends transversely to terminal 7 with minimal loss.

FIG. 6 shows the configuration of the feedthrough in the central region (11 in FIG. 2).

In the central region, the feedthrough is configured as a coaxial conductor.

The coaxial conductor is formed by signal conductor vias 18c stacked one upon another, which are surrounded by a circular recess 24 of each respective ground layer 16c.

Configured as the outer conductor of a coaxial line, ground vias 19 are provided annularly arranged around circular recess 24, for interconnecting the ground layers 16c provided on the ceramic layers.

Because of this configuration as a coaxial conductor, ceramic layers may be added or omitted in the central region without changing impedance.

Therefore, the feedthrough may be easily adapted to different heights as desired.

FIG. 7 shows a wireframe view of the lower region of the feedthrough (10 in FIG. 2). In particular, mutually offset signal conductor vias 18c and 18d can be seen, through which the signal is now guided from the vertical direction in the central region to the horizontal direction of lower terminal 6 which is surrounded by ground terminals 17.

Moreover, circular recesses 24 in the individual ground layers are clearly visible.

In contrast to the exemplary embodiment of FIG. 3 and FIG. 4, ground vias 19 are stacked to one another and are not offset from one another.

The invention permits to provide a radio frequency feedthrough for optoelectronic housings which is easy to produce and which is SMD compatible.

### LIST OF REFERENCE NUMERALS

1 Housing
2 Optical input
3a, 3b Terminal, outside
4a, 4b Terminal, inside
5 Feedthrough
6 Lower terminal
7 Upper terminal
8 Ceramic body
9 Signal conductor
10 Lower region
11 Central region
12 Upper region
13 Frame
14 Metal layer
15 Ceramic layer
16a, 16b Ground layer
17 Ground terminal
18a-18e Signal conductor via
19 Ground via
20 Circuit board
21a, 21b Ceramic layer
22 V-shaped recess
23 Conductive trace
24 Circular recess
25 Extension
26 Metallization

What is claimed is:

1. An SMD compatible feedthrough for radio frequency signals, comprising:
a multilayer ceramic body;
at least one signal conductor extending through the multilayer ceramic body;
a first, lower terminal; and
a second, upper terminal spaced in a vertical direction from the first, lower terminal,
wherein the multilayer ceramic body has layers and ground layers, the ground layers having a recess around the at least one signal conductor and being connected to each other by ground vias extending through the layers, and
wherein, in the ground layer of the second, upper terminal, the recess around the signal conductor widens behind an end of the second, upper terminal.

2. The SMD compatible feedthrough as claimed in claim 1, wherein the recess widens in a V-shape.

3. The SMD compatible feedthrough as claimed in claim 2, wherein the recess have edges that form an angle (α) of between 20° and 90°.

4. The SMD compatible feedthrough as claimed in claim 2, wherein the recess have edges that form an angle (α) of between 30° and 60°.

5. The SMD compatible feedthrough as claimed in claim 1, wherein the ground layers below a first layer are substantially circularly recessed around the signal conductor.

6. The SMD compatible feedthrough as claimed in claim 5, wherein, in a ground layer below the widening recess, an extension protrudes into the circular recess below the signal conductor.

7. The SMD compatible feedthrough as claimed in claim 6, wherein the extension is wider than the signal conductor.

8. The SMD compatible feedthrough as claimed in claim 1, wherein the ground vias comprise a plurality of individual conductors annularly arranged around the signal conductor.

9. The SMD compatible feedthrough as claimed in claim 8, wherein the individual conductors are arranged offset to one another from layer-to-layer of the multiplayer ceramic body.

10. The SMD compatible feedthrough as claimed in claim 1, wherein the signal conductor extends through the multilayer ceramic body in an S-shape.

11. The SMD-compatible feedthrough as claimed in claim 1, wherein the multilayer ceramic body is formed as a sintered HTCC multilayer body.

12. The SMD-compatible feedthrough as claimed in claim 1, wherein the signal conductor extends from the first, lower terminal through a plurality of signal conductor vias that are arranged offset and connected to each other, and in a vertical direction.

13. The SMD-compatible feedthrough as claimed in claim 12, wherein, in a central region, the signal conductor is formed by superimposed signal conductor vias that are arranged coaxially in recesses of the ground layers.

14. The SMD-compatible feedthrough as claimed in claim 13, wherein, in an upper region, the signal conductor extends through signal conductor vias that are arranged offset and connected to each other, and in a horizontal direction.

15. The SMD compatible feedthrough as claimed in claim 1, wherein, above a layer of the second, upper terminal, at least one further layer is arranged that is formed as a frame for mounting a housing part.

16. The SMD compatible feedthrough as claimed in claim 15, wherein the frame comprises a plurality of ceramic layers, wherein an underneath layer occupies at least an area of the overlying layer.

17. The SMD compatible feedthrough as claimed in claim 1, wherein the multilayer ceramic body comprises from 5 to 100 layers.

18. The SMD compatible feedthrough as claimed in claim 1, wherein the multilayer ceramic body comprises from 10 to 25 layers.

19. A housing for an ICR or ICT module, comprising at least one SMD compatible feedthrough as claimed in claim 1.
